(19) United States
(12) Patent Application Publication
(10) Pub. No.: US 2024/0333243 A1
(43) Pub. Date: Oct. 3, 2024

(54) METHOD OF MANUFACTURING RESONATOR ELEMENT, RESONATOR ELEMENT, AND RESONATOR DEVICE

(71) Applicant: SEIKO EPSON CORPORATION, Tokyo (JP)

(72) Inventors: Yusuke Yamamoto, Minowa-machi (JP); Keiichi Yamaguchi, Ina-shi (JP); Ryuta Nishizawa, Nagano-shi (JP)

(21) Appl. No.: 18/618,488

(22) Filed: Mar. 27, 2024

(30) Foreign Application Priority Data
Mar. 29, 2023 (JP) 2023-052983

(51) Int. Cl. H03H 3/02; H03H 9/10; H03H 9/13; H03H 9/19

(52) U.S. Cl. CPC H03H 3/02; H03H 9/1021; H03H 9/132; H03H 9/19; H03H 2003/022

(57) ABSTRACT

A method of manufacturing a resonator element including a substrate having a thin-wall part and a thick-wall part, and an electrode part having an excitation electrode arranged in an excitation electrode placement area of the thin-wall part, a pad electrode arranged in a pad electrode placement area of the thick-wall part, and an extraction electrode which is configured to couple the excitation electrode and the pad electrode to each other, and which is arranged in an extraction electrode placement area of the substrate, includes a metal layer formation step of forming a metal layer on the substrate, a protective film formation step of forming a protective film in an area overlapping at least a part of the extraction electrode placement area in a plan view on the metal layer, and a metal layer etching step of etching the metal layer arranged in the excitation electrode placement area via the protective film to thereby reduce a wall thickness of the metal layer.

The present application is based on, and claims priority from JP Application Serial Number 2023-052983, filed Mar. 29, 2023, the disclosure of which is hereby incorporated by reference herein in its entirety.

### BACKGROUND

### 1. Technical Field

The present disclosure relates to a method of manufacturing a resonator element, a resonator element, and a resonator device.

### 2. Related Art

JP-A-2014-7693 (Document 1) discloses a piezoelectric resonator element having a so-called inverted mesa structure in which a recessed portion is formed in a part of a principal surface to achieve a higher frequency. This piezoelectric resonator element has a slit disposed between a thick-wall part for fixing the piezoelectric resonator element and a vibrating part in order to suppress the spread of stress caused by bonding/fixing. Further, the thickness of an extraction electrode is made thicker than the thickness of an excitation electrode in order to prevent an increase in sheet resistance in particular in the extraction electrode small in width for electrically coupling the excitation electrode and a pad electrode to each other due to a reduction in film thickness of an electrode for achieving the higher frequency.

However, in the piezoelectric resonator element in Document 1, in order to make the thickness of the extraction electrode thicker than the thickness of the excitation electrode, the extraction electrode is formed, and then the extraction electrode having the same thickness as the thickness of the excitation electrode is formed so as to be stacked on a part of that extraction electrode. Further, the thin extraction electrode is formed in a stacked manner so as to straddle a step as an end portion of the thick extraction electrode formed in advance. Therefore, there is a problem that the extraction electrode formed subsequently in the step portion is easy to break.

### SUMMARY

A method of manufacturing a resonator element including a substrate having a thin-wall part and a thick-wall part larger in thickness than the thin-wall part, and an electrode part having an excitation electrode arranged in an excitation electrode placement area of the thin-wall part, a pad electrode arranged in a pad electrode placement area of the thick-wall part, and an extraction electrode which is configured to couple the excitation electrode and the pad electrode to each other, and which is arranged in an extraction electrode placement area of the substrate, includes a metal layer formation step of forming a metal layer on the substrate, a protective film formation step of forming a protective film in an area overlapping at least a part of the extraction electrode placement area in a plan view on the metal layer, and a metal layer etching step of etching the metal layer arranged in the excitation electrode placement area via the protective film to thereby reduce a wall thickness of the metal layer.

A resonator element includes a substrate having a thin-wall part and a thick-wall part larger in thickness than the thin-wall part, and an electrode part having an excitation electrode arranged in an excitation electrode placement area of the thin-wall part, a pad electrode arranged in a pad electrode placement area of the thick-wall part, and an extraction electrode which is configured to couple the excitation electrode and the pad electrode to each other, and which is arranged in an extraction electrode placement area of the substrate, wherein the electrode part includes a first electrode layer arranged in the pad electrode placement area, the extraction electrode placement area, and the excitation electrode placement area on the substrate, and a second electrode layer which is arranged in an area overlapping the pad electrode placement area, the extraction electrode placement area, and the excitation electrode placement area in a plan view on the first electrode layer, and which is larger in thickness than the first electrode layer, and the second electrode layer includes an electrode thin-wall part overlapping the excitation electrode placement area in a plan view, and an electrode thick-wall part which overlaps the extraction electrode placement area, and which is larger in thickness than the electrode thin-wall part.

A resonator device includes the resonator element described above, and a package in which the resonator element is housed, and to which the resonator element is fixed via a bonding member.

### BRIEF DESCRIPTION OF THE DRAWINGS

FIG. 1 is a perspective view showing a configuration of a resonator element according to a first embodiment.

FIG. 2 is a diagram for explaining a relationship between an AT-cut crystal substrate and crystal axes of quartz crystal.

FIG. 3 is a plan view of the resonator element shown in FIG. 1.

FIG. 4 is a cross-sectional view along the line A1-A1 in FIG. 3.

FIG. 5 is a cross-sectional view along the line A2-A2 in FIG. 3.

FIG. 6 is a cross-sectional view along the line A3-A3 in FIG. 3.

FIG. 7 is a flowchart showing a method of manufacturing the resonator element.

FIG. 8 is a cross-sectional view for explaining the method of manufacturing the resonator element.

FIG. 9 is a cross-sectional view for explaining the method of manufacturing the resonator element.

FIG. 10 is a cross-sectional view for explaining the method of manufacturing the resonator element.

FIG. 11 is a cross-sectional view for explaining the method of manufacturing the resonator element.

FIG. 12 is a cross-sectional view for explaining the method of manufacturing the resonator element.

FIG. 13 is a cross-sectional view for explaining the method of manufacturing the resonator element.

FIG. 14 is a cross-sectional view for explaining the method of manufacturing the resonator element.

FIG. 15 is a plan view showing a configuration of a resonator element according to a second embodiment.

FIG. 16 is a cross-sectional view along the line B1-B1 in FIG. 15.

FIG. 17 is a perspective view showing a configuration of a resonator element according to a third embodiment.

FIG. 18 is a cross-sectional view showing a configuration of a resonator device according to a fourth embodiment.

### DESCRIPTION OF EXEMPLARY EMBODIMENTS

### 1. First Embodiment

### 1.1. Resonator Element

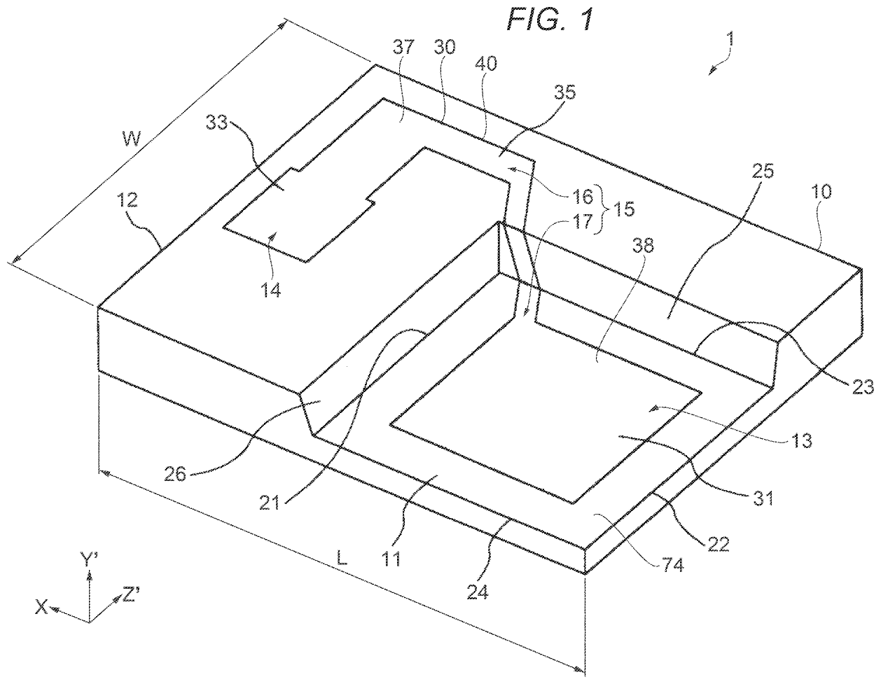

A resonator element 1 according to a first embodiment will be described with reference to FIG. 1 through FIG. 6.

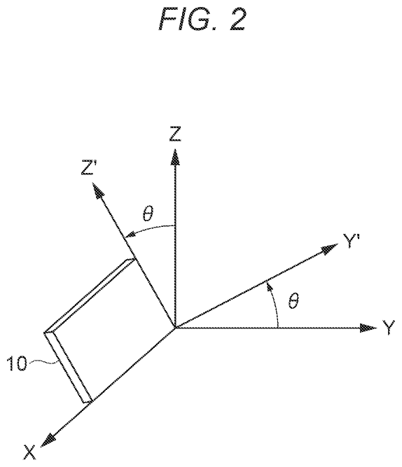

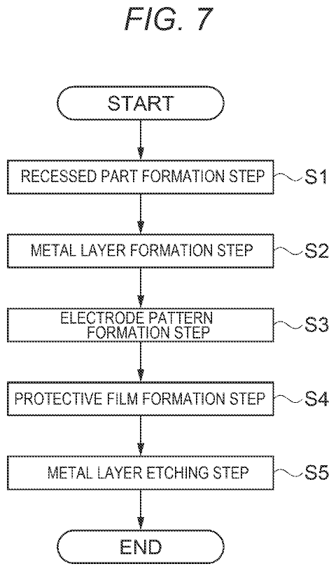

It should be noted that an X axis, a Y′ axis, and a Z′ axis are shown as three axes perpendicular to each other in the drawings hereinafter described except FIG. 2 and FIG. 7 for the sake of convenience of explanation. Further, a longitudinal direction of the resonator element 1 is referred to as an “X direction” as a direction along the X axis, a thickness direction of the resonator element 1 is referred to as a “Y′ direction” as a direction along the Y′ axis, and a direction perpendicular to the X axis and the Y′ axis is referred to as a “Z′ direction” as a direction along the Z′ axis. Further, an arrow side of each of the axes is also referred to as a “positive side,” and an opposite side to the arrow is also referred to as a “negative side.” Further, a positive side in the Y′ direction is also referred to as an “obverse side,” and a negative side in the Y′ direction is also referred to as a “reverse side.”

As shown in FIG. 1, the resonator element 1 according to the present embodiment has a substrate 10, and an electrode part 30 formed on the substrate 10.

The substrate 10 is a crystal substrate having a plate-like shape. Here, the quartz crystal as the material of the substrate 10 belongs to a trigonal system, and has crystal axes X, Y, and Z perpendicular to each other as shown in FIG. 2. The X axis, the Y axis, and the Z axis are called an electrical axis, a mechanical axis, and an optical axis, respectively. The substrate 10 in the present embodiment is a “rotated Y-cut crystal substrate” carved out along a plane obtained by rotating the X-Z plane around the X axis as much as a predetermined angle θ, and the substrate curved out along a plane obtained by the rotation as much as, for example, 0=35° 15′ is referred to as an “AT-cut crystal substrate.” By using such a crystal substrate, the resonator element 1 having superior temperature characteristics is obtained.

It should be noted that the substrate 10 is not limited to the AT-cut crystal substrate providing the thickness-shear vibration can be excited, and for example, a BT-cut crystal substrate can also be used. Further, as the substrate 10, it is possible to use a variety of piezoelectric made of, for example, lithium niobate or lithium tantalate besides the crystal substrate.

It should be noted that the Y axis and the Z axis rotated around the X axis in accordance with the angle θ are hereinafter referred to as the Y′ axis and the Z′ axis, respectively. In other words, the substrate 10 has a thickness in the Y′ direction, and has a spread in the X-Z′ plane direction.

The substrate 10 forms a longitudinal shape having a long side in the X direction, and a short side in the Z′ direction in a plan view. Further, the substrate 10 has a tip side at the −X direction side and a base end side at the +X direction side. Defining a maximum length in the X direction of the substrate 10 as L, and a maximum width in the Z′ direction thereof as W, a value L/W is not particularly limited, but is preferably set to, for example, about 1.1 through 1.4.

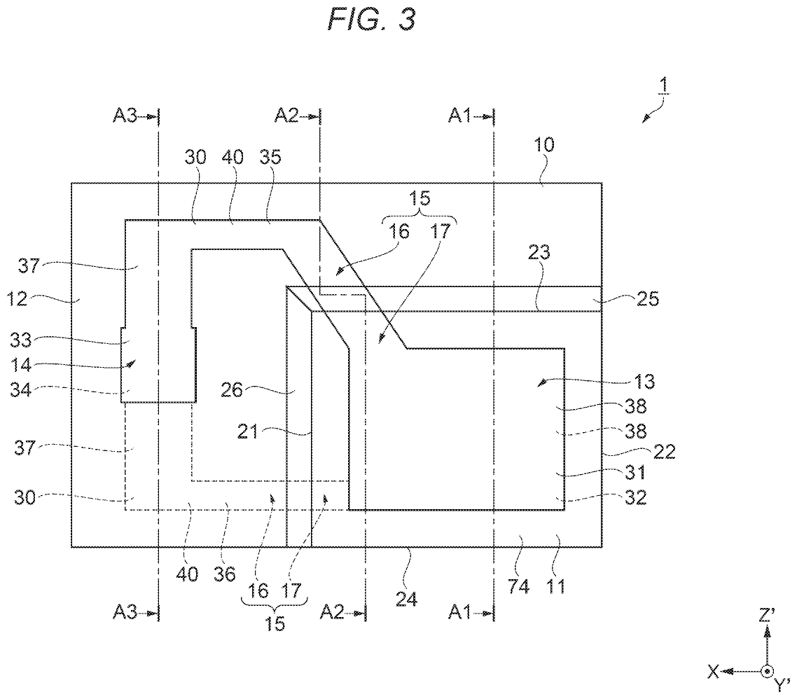

As shown in FIG. 1 and FIG. 3, the substrate 10 has a thin-wall part 11 in a vibrating region as a region where the vibration energy is confined, and a thick-wall part 12 which is integrated with the thin-wall part 11, and which is larger in thickness than the thin-wall part 11. It should be noted that the thin-wall part 11 is formed by etching the substrate 10 in the −Y′ direction to form a recessed portion 74.

The thin-wall part 11 is displaced toward the negative side in the X direction and the negative side in the Z′ direction from the center of the substrate 10, and a part of an outer edge of the thin-wall part 11 is exposed from the thick-wall part 12. It is preferable that the area of the thin-wall part 11 is equal to or smaller than a half of the area of the substrate 10 in a plan view of the resonator element 1. Thus, it is possible to form the thick-wall part 12 higher in mechanical strength to be sufficiently large, and therefore, it is possible to sufficiently ensure the rigidity of the thin-wall part 11. In the plan view of the resonator element 1, the thin-wall part 11 has a first outer edge 21 and a second outer edge 22 which are distant in the X direction as a vibration direction of the thickness-shear vibration from each other, and which extend in the Z′ direction, and a third outer edge 23 and a fourth outer edge 24 which are distant in the Z′ direction from each other, and which extend in the X direction. Out of the first outer edge 21 and the second outer edge 22, the first outer edge 21 is located at the positive side in the X direction, and the second outer edge 22 is located at the negative side in the X direction. Further, out of the third outer edge 23 and the fourth outer edge 24, the third outer edge 23 is located at the positive side in the Z′ direction, and the fourth outer edge 24 is located at the negative side in the Z′ direction. Further, the third outer edge 23 couples ends at the positive side in the Z′ direction of the first outer edge 21 and the second outer edge 22 to each other, and the fourth outer edge 24 couples ends at the negative side in the Z′ direction of the first outer edge 21 and the second outer edge 22 to each other.

Further, as shown in FIG. 1, an obverse surface as the principal surface at the positive side in the Y′ direction of the thick-wall part 12 is disposed so as to protrude toward the positive side in the Y′ direction from the obverse surface as the principal surface at the positive side in the Y′ direction of the thin-wall part 11. In contrast, a reverse surface as the principal surface at the negative side in the Y′ direction of the thick-wall part 12 is disposed on the same plane as the reverse surface as the principal surface at the negative side in the Y′ direction of the thin-wall part 11.

The thick-wall part 12 includes the thick-wall part 12 arranged along the first outer edge 21 and the thick-wall part 12 arranged along the third outer edge 23. Therefore, the thick-wall part 12 is provided with a structure of bending along the thin-wall part 11, and has a substantially L shape in the plan view. On the other hand, the thick-wall part 12 is not formed along the second outer edge 22 and the fourth outer edge 24 of the thin-wall part 11, and the second outer edge 22 and the fourth outer edge 24 are exposed from the thick-wall part 12. As described above, by partially disposing the thick-wall part 12 along the outer edges of the thin-wall part 11 to have the substantially L shape, and preventing the thick-wall part 12 from being disposed along the second outer edge 22 and the fourth outer edge 24, it is possible to reduce the mass at the tip side of the resonator element 1 while keeping the rigidity of the thin-wall part 11 of the resonator element 1. Further, it is possible to achieve a reduction in size of the resonator element 1.

The thick-wall part 12 is provided with a connection part 26 and a connection part 25 for connecting the thick-wall part 12 and the thin-wall part 11 to each other, wherein the connection part 26 is disposed continuously to the first outer edge 21, and has a tilted part gradually increasing in thickness toward the +X direction, and the connection part 25 is disposed continuously to the third outer edge 23, and has a tilted part gradually increasing in thickness toward the +Z′ direction. Further, the thick-wall part 12 at the connection part 26 side forms a mount part, and is fixed to a package or the like using an electrically-conductive adhesive or the like.

The electrode part 30 has a pair of excitation electrodes 31, 32, a pair of pad electrodes 33, 34, and a pair of extraction electrodes 35, 36.

The excitation electrodes 31, 32 are arranged in an excitation electrode placement area 13 of the thin-wall part 11. The excitation electrode 31 is formed on the obverse surface of the thin-wall part 11. In contrast, the excitation electrode 32 is arranged on the reverse surface of the thin-wall part 11 so as to be opposed to the excitation electrode 31. The excitation electrodes 31, 32 each have a substantially rectangular shape setting the longitudinal direction to the X direction, and the short-side direction to the Z′ direction.

The pad electrodes 33, 34 are arranged in a pad electrode placement area 14 of the thick-wall part 12. The pad electrode 33 is formed on the obverse surface of the thick-wall part 12 at the connection part 26 side. On the other hand, the pad electrode 34 is formed on the reverse surface of the thick-wall part 12 at the connection part 26 side so as to be opposed to the pad electrode 33.

The extraction electrodes 35, 36 are arranged in an extraction electrode placement area 15 of the substrate 10. It should be noted that the extraction electrode placement area 15 is constituted by a first area 16 including a portion located in the thick-wall part 12 including the connection parts 25, 26, and a second area 17 including a portion located in the thin-wall part 11. The extraction electrode 35 electrically couples the excitation electrode 31 and the pad electrode 33 to each other. On the other hand, the extraction electrode 36 electrically couples the excitation electrode 32 and the pad electrode 34 to each other. The extraction electrodes 35, 36 are disposed so as not to overlap each other via the substrate 10. Thus, it is possible to suppress the capacitance between the extraction electrodes 35, 36.

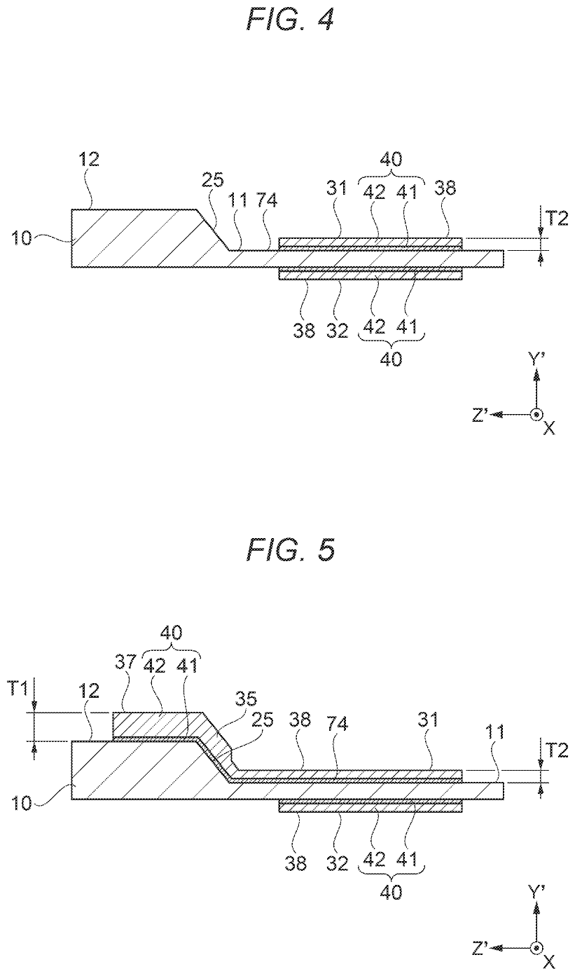

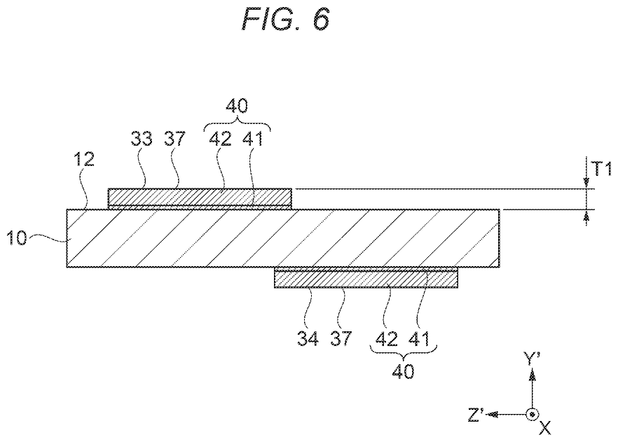

Further, as shown in FIG. 3, FIG. 4, FIG. 5, and FIG. 6, the electrode part 30 is constituted by a first electrode layer 41 and a second electrode layer 42, wherein the first electrode layer 41 is arranged in the pad electrode placement area 14, the extraction electrode placement area 15, and the excitation electrode placement area 13 on the substrate 10, and the second electrode layer 42 is arranged in an area overlapping the pad electrode placement area 14, the extraction electrode placement area 15, and the excitation electrode placement area 13 on the first electrode layer 41 in a plan view, and is larger in thickness than the first electrode layer 41.

The second electrode layer 42 is provided with an electrode thin-wall part 38 overlapping the excitation electrode placement area 13, and an electrode thick-wall part 37 which overlaps the extraction electrode placement area 15, and which is larger in thickness than the electrode thin-wall part 38 in a plan view, wherein the electrode thin-wall part 38 is arranged in the second area 17 of the excitation electrode placement area 13 and the extraction electrode placement area 15 on the thin-wall part 11, and the electrode thick-wall part 37 is arranged in the first area 16 of the pad electrode placement area 14 and the extraction electrode placement area 15 on the thick-wall part 12 including the connection parts 25, 26.

Specifically, the electrode thin-wall part 38 corresponds to the excitation electrodes 31, 32 and the extraction electrodes 35, 36 on the thin-wall part 11, and the electrode thick-wall part 37 corresponds to the pad electrodes 33, 34 and the extraction electrodes 35, 36 on the thick-wall part 12 including the connection parts 25, 26.

It should be noted that the electrode thin-wall part 38 is formed by etching a metal layer 40 having the same thickness as the thickness T1 of the electrode thick-wall part 37 until the thickness T2 is achieved. Therefore, the surface of the electrode thin-wall part 38 at an opposite side to the substrate 10 is an etched surface. Further, when the etching is performed using a dry etching process, the surface of the electrode thin-wall part 38 at the opposite side to the substrate 10 is a dry-etched surface.

Further, since the electrode thin-wall part 38 and the electrode thick-wall part 37 in each of the extraction electrodes 35, 36 are formed integrally with each other, there is no possibility of breaking, and since a large part of each of the extraction electrodes 35, 36 narrow in width is formed of the electrode thick-wall part 37, it is possible to control an increase in sheet resistance.

It should be noted that it is preferable for the thickness T1 of the electrode thick-wall part 37 and the thickness T2 of the electrode thin-wall part 38 to fulfill 0.05≤T2/T1≤0.7. When T2/T1 is smaller than 0.05, the thickness of the extraction electrodes 35, 36 is too thin to sufficiently suppress the increase in sheet resistance. Further, when T2/T1 is greater than 0.7, the etching time for forming the electrode thin-wall part 38 becomes too long, and thus, the manufacturing cost increases.

The constituent material of the electrode part 30 is gold (Au) in the second electrode layer 42, and is at least one of nickel (Ni), chromium (Cr), and chromium nitride (CrN) in the first electrode layer 41.

As described hereinabove, in the resonator element 1 according to the present embodiment, the pad electrodes 33, 34 and the extraction electrodes 35, 36 on the thick-wall part 12 including the connection parts 25, 26 of the substrate 10 are formed of the electrode thick-wall part 37, and the excitation electrodes 31, 32 and the extraction electrodes 35, 36 on the thin-wall part 11 are formed of the electrode thin-wall part 38. Therefore, it is possible to set the thickness of the excitation electrodes 31, 32 to a thickness with which unwanted spurious is difficult to occur, and to set the thickness of the extraction electrodes 35, 36 to a thickness with which the sheet resistance is difficult to increase. Therefore, it is possible to obtain the resonator element 1 which is excellent in vibration characteristics, and is excellent in electrical reliability.

### 1.2. Method of Manufacturing Resonator Element

Then, a method of manufacturing the resonator element 1 will be described with reference to FIG. 7 through FIG. 14.

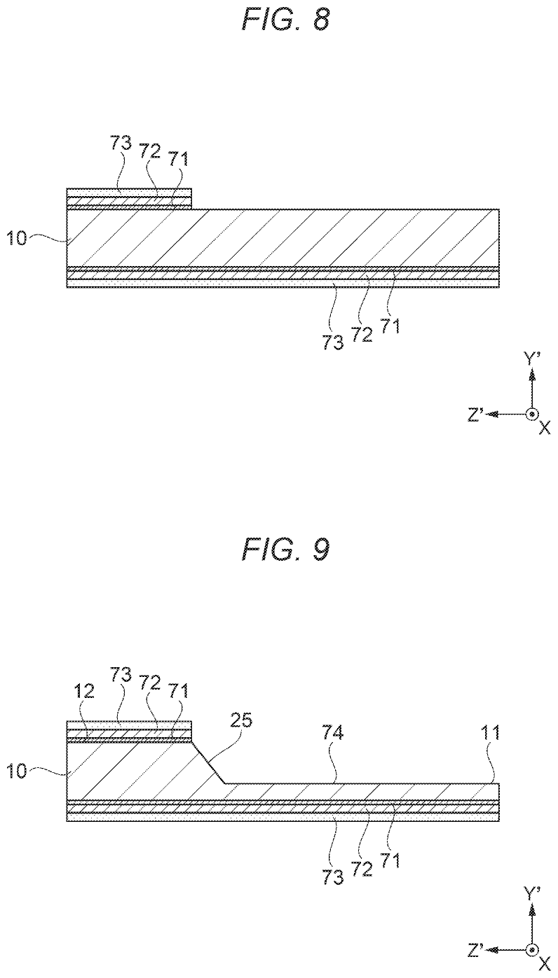

It should be noted that FIG. 8 through FIG. 14 are each a cross-sectional view corresponding to the position of the cross-sectional view along the line A2-A2 shown in FIG. 3.

As shown in FIG. 7, the method of manufacturing the resonator element 1 according to the present embodiment includes a recessed portion formation step, a metal layer formation step, an electrode pattern formation step, protective film formation step, and a metal layer etching step.

### 1.2.1. Recessed Part Formation Step

In the step S1, a foundation film 71 made of chromium (Cr) or the like and a metal film 72 made of gold (Au) or the like are deposited on the entire surface of the substrate 10 in the order of the foundation film 71 and the metal film 72 using a sputtering apparatus or an evaporation apparatus. Then, a protective film 73 such as a resist is applied on the metal film 72, and then a recessed portion pattern is formed as shown in FIG. 8 using a photolithography technology.

Wet etching is performed on the substrate 10 on which the recessed portion pattern is formed using an etching liquid such as a compound liquid of hydrofluoric acid and ammonium fluoride to provide the recessed portion 74 to the substrate 10 as shown in FIG. 9. Due to this step, the thin-wall part 11 and the thick-wall part 12 are provided to the substrate 10.

### 1.2.2. Metal Layer Formation Step

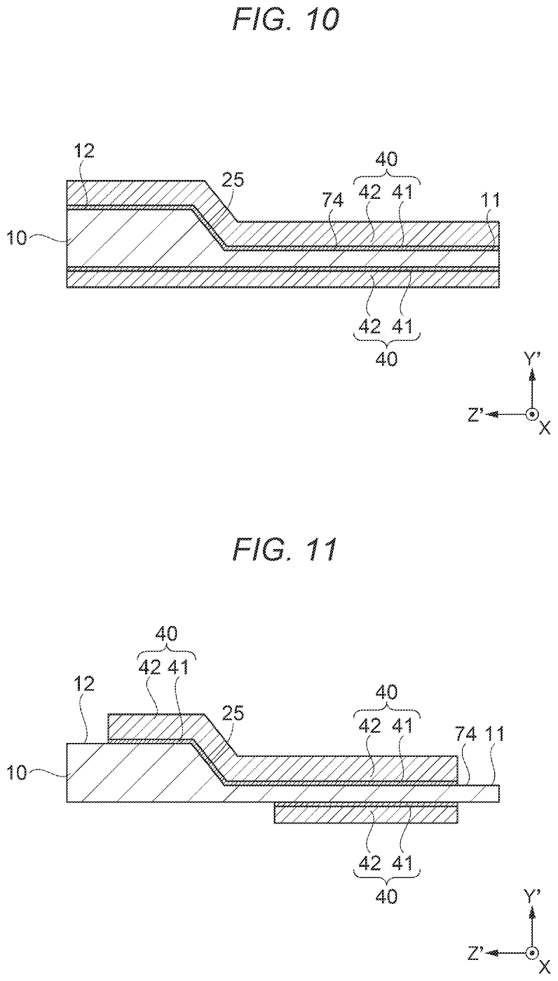

In the step S2, after removing the foundation film 71, the meal film 72, and the protective film 73, the first electrode layer 41 formed of chromium (Cr) or the like and the second electrode layer 42 formed of gold (Au) or the like are deposited on the entire surface of the substrate 10 provided with the recessed portion 74 in the order of the first electrode layer 41 and the second electrode layer 42 using the sputtering apparatus or the evaporation apparatus to form the metal layer 40 on the substrate 10 as shown in FIG. 10. It should be noted that the thickness of the metal layer 40 is T1.

### 1.2.3. Electrode Pattern Formation Step

In the step S3, the electrode pattern is provided to the metal layer 40 on the substrate 10 as shown in FIG. 11 using the photolithography technology and the etching technology. More specifically, the excitation electrodes 31, 32 are formed in the excitation electrode placement area 13, the pad electrodes 33, 34 are formed in the pad electrode placement area 14, and the extraction electrodes 35, 36 are formed in the extraction electrode placement area 15.

### 1.2.4. Protective Film Formation Step

In the step S4, the protective film 75 such as a resist is applied on the substrate 10 provided with the electrode pattern of the metal layer 40, and then, the protective film 75 is formed in an area overlapping at least a part of the extraction electrode placement area 15 on the metal layer 40 as shown in FIG. 12 using the photolithography technology. More specifically, the protective film 75 is formed in the pad electrode placement area 14 and an area overlapping the first area 16 of the extraction electrode placement area 15 of the thick-wall part 12 including the connection parts 25, 26.

### 1.2.5. Metal Layer Etching Step

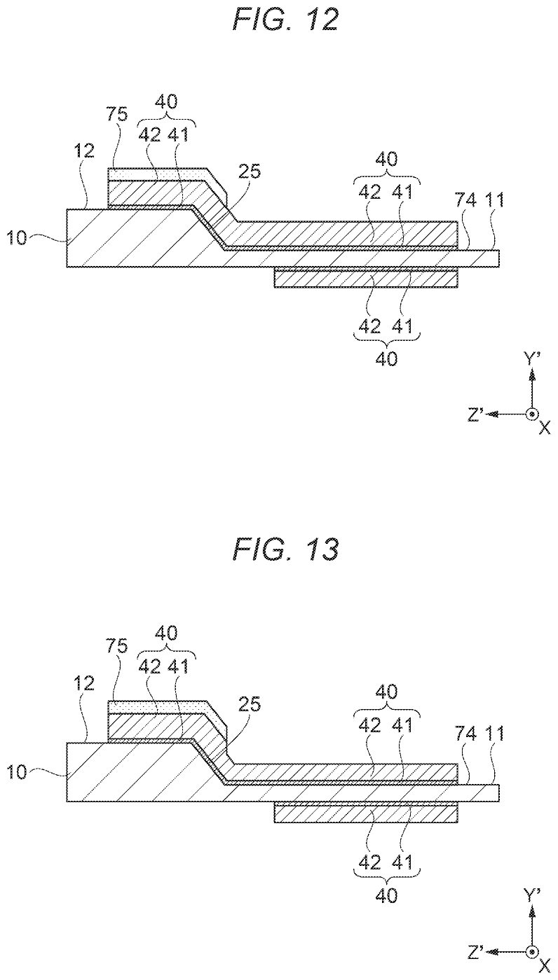

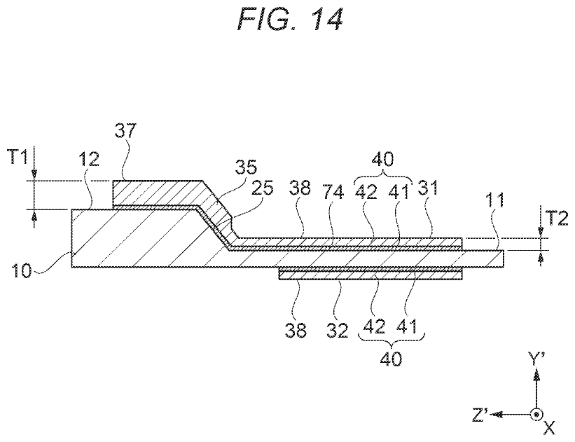

As shown in FIG. 13, in the step S5, the etching is performed via the protective film 75 to reduce the wall thickness of the metal layer 40 arranged in the second area 17 of the extraction electrode placement area 15 and the excitation electrode placement area 13. By stopping the etching at the time point when the thickness T2 of the metal layer 40 reaches the thickness which fulfills 0.05≤T2/T1≤0.7, the resonator element 1 which is completed can be obtained as shown in FIG. 14. It should be noted that the method of etching the metal layer 40 to reduce the wall thickness of the metal layer 40 can be either one of dry etching using a dry etching apparatus and wet etching using an etching liquid. Dry etching has an advantage that it is easy to control the thickness T2 of the metal layer 40 compared to wet etching.

Due to the manufacturing method described hereinabove, it is possible to manufacture the resonator element 1 in which the pad electrodes 33, 34 and the extraction electrode 35, 36 formed of the electrode thick-wall part 37 are disposed in the thick-wall part 12 including the connection parts 25, 26 of the substrate 10, and the excitation electrodes 31, 32 and the extraction electrodes 35, 36 formed of the electrode thin-wall part 38 are disposed in the thin-wall part 11. Therefore, it is possible to set the thickness of the excitation electrodes 31, 32 to a thickness with which unwanted spurious is difficult to occur, and to set the thickness of the extraction electrodes 35, 36 to a thickness with which the sheet resistance is difficult to increase. Therefore, it is possible to obtain the resonator element 1 which is excellent in vibration characteristics, and is excellent in electrical reliability.

### 2. Second Embodiment

### 2.1. Resonator Element

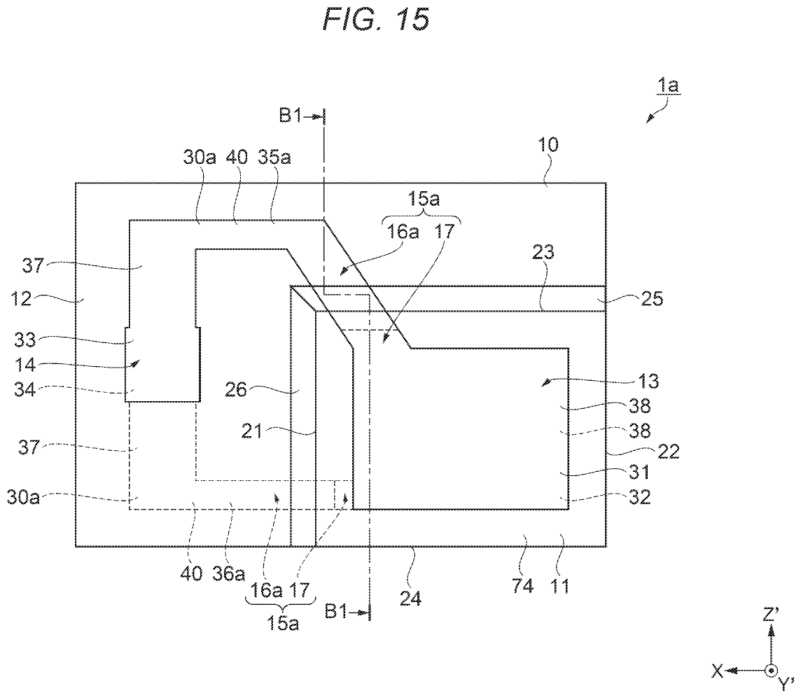

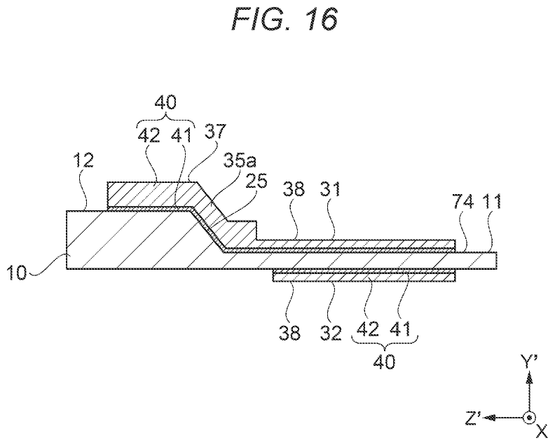

Then, a resonator element 1a according to a second embodiment will be described with reference to FIG. 15 and FIG. 16.

The resonator element 1a according to the present embodiment is substantially the same as the resonator element 1 according to the first embodiment except the point that an electrode placement position configuration of an electrode part 30a is different from that of the first resonator element 1 according to the first embodiment. It should be noted that there is presented the description with a focus on the differences from the first embodiment described above, and regarding substantially the same matters, the same reference symbols are provided, and the explanation thereof will be omitted.

As shown in FIG. 15, the resonator element 1a has the substrate 10, and the electrode part 30a formed on the substrate 10.

The electrode part 30a of the resonator element 1a is constituted by the pad electrodes 33, 34 formed of the electrode thick-wall part 37, extraction electrodes 35a, 36a formed of the electrode thick-wall part 37 and the electrode thin-wall part 38, and the excitation electrodes 31, 32 formed of the electrode thin-wall part 38. A first area 16a of an extraction electrode placement area 15a where the extraction electrodes 35a, 36a formed of the electrode thick-wall part 37 are formed includes a portion located in the thin-wall part 11. In other words, as shown in FIG. 16, the extraction electrode 35a formed of the electrode thick-wall part 37 is provided to the thick-wall part 12 including the connection part 25 and a part of the thin-wall part 11.

A method of manufacturing the resonator element 1a according to the present embodiment is the same as the method of manufacturing the resonator element 1 according to the first embodiment, and in the protective film formation step in the step S4, the protective film 75 is formed in the pad electrode placement area 14 and an area overlapping the first area 16a located in the thin-wall part 11 and the connection parts 25, 26 in the plan view on the metal layer 40. Due to this step, it is possible to form the extraction electrode 35a formed of the electrode thick-wall part 37 in the first area 16a of the thick-wall part 12 including the connection parts 25, 26 and the thin-wall part 11.

By adopting such a configuration in the resonator element 1a, it is possible to shorten the extraction electrodes 35a, 36a formed of the electrode thin-wall part 38, and thus, it is possible to further suppress the increase in sheet resistance. Therefore, it is possible to obtain the resonator element 1a which does not have a possibility of breaking, which is excellent in electrical connection reliability, and which is low in CI value.

### 3. Third Embodiment

### 3.1. Resonator Element

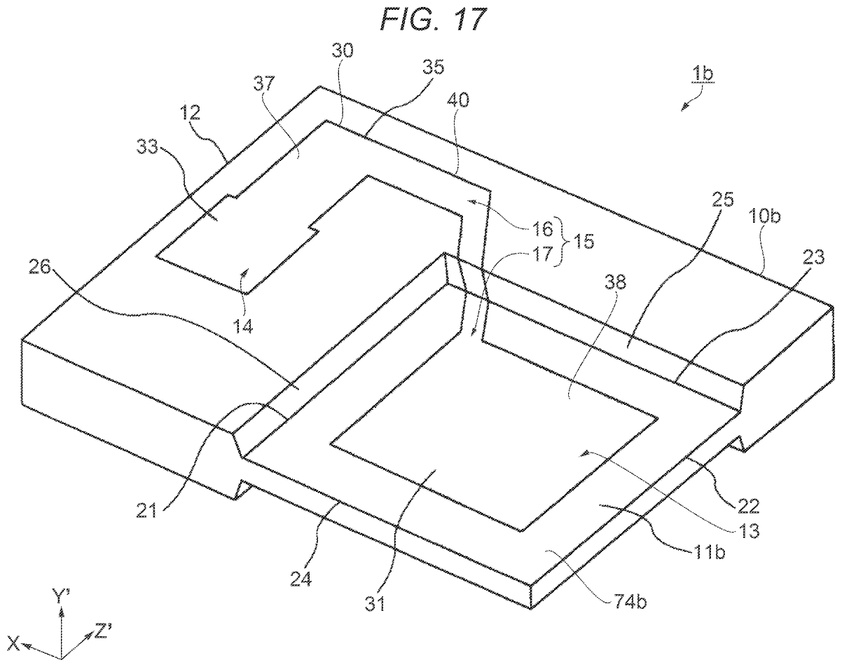

Then, a resonator element 1b according to a third embodiment will be described with reference to FIG. 17.

The resonator element 1b according to the present embodiment is substantially the same as the resonator element 1 according to the first embodiment except the point that a shape of a substrate 10b is different from that of the first resonator element 1 according to the first embodiment. It should be noted that there is presented the description with a focus on the differences from the first embodiment described above, and regarding substantially the same matters, the same reference symbols are provided, and the explanation thereof will be omitted.

As shown in FIG. 17, the resonator element 1b has the substrate 10b, and the electrode part 30 formed on the substrate 10b.

In the substrate 10b of the resonator element 1b, the obverse surface as the principal surface at the positive side in the Y′ direction of the thick-wall part 12 is disposed so as to protrude toward the positive side in the Y′ direction from the obverse surface as the principal surface at the positive side in the Y′ direction of a thin-wall part 11b. Meanwhile, a reverse surface as the principal surface at the negative side in the Y′ direction of the thick-wall part 12 is disposed so as to protrude toward the negative side in the Y′ direction from the reverse surface as the principal surface at the negative side in the Y′ direction of the thin-wall part 11b. In other words, the thin-wall part 11b is formed by forming recessed portions 74b on the both surfaces of the substrate 10b. Therefore, in the manufacturing method, it is possible to make the etching depth of the recessed portions 74b shallower to achieve a reduction in cost compared to the first embodiment described above.

By adopting such a configuration to the resonator element 1b, it is possible to obtain the resonator element 1b which does not have a possibility of breaking, which is excellent in electrical connection reliability, and which is low in cost.

### 4. Fourth Embodiment

### 4.1. Resonator Device

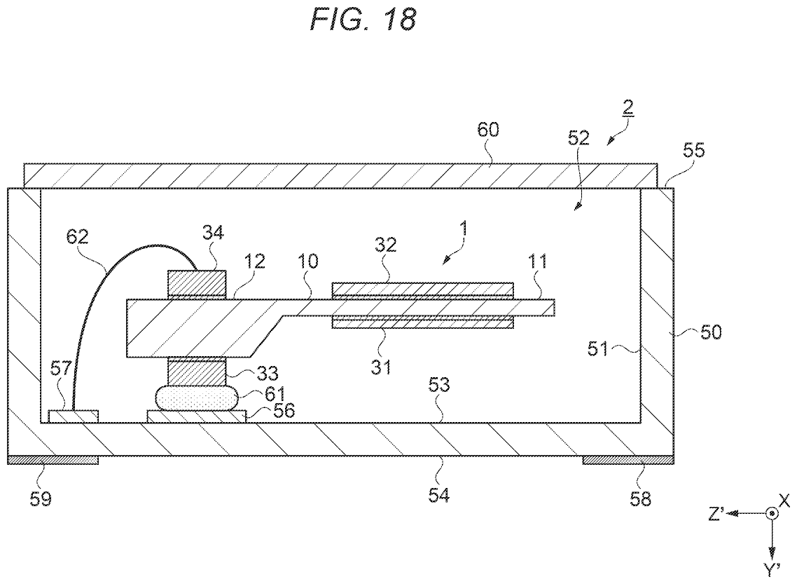

Then, a resonator device 2 according to a fourth embodiment will be described with reference to FIG. 18. It should be noted that in the present description, the explanation is presented citing the resonator device 2 equipped with the resonator element 1 described above as an example.

As shown in FIG. 18, the resonator device 2 has the resonator element 1, a package 50 for housing the resonator element 1, and a lid 60 for forming a housing space 52 with the package 50.

The package 50 has a recess 51 opening on a first surface 55, and the lid 60 for covering the opening of the recess 51 is bonded to the first surface 55. By covering the recess 51 of the package 50 with the lid 60, the housing space 52 for housing the resonator element 1 is formed. The housing space 52 can be kept in a reduced-pressure state or a vacuum state, or can be filled with an inert gas such as nitrogen (N), helium (He), or argon (Ar).

The constituent material of the package 50 is not particularly limited, and a variety of types of ceramics such as aluminum oxide can be used as the constituent material. Further, the constituent material of the lid 60 is not particularly limited, and a member with a linear expansion coefficient similar to that of the constituent material of the package 50 is preferable. It should be noted that bonding between the package 50 and the lid 60 is not particularly limited, and it is possible to bond the package 50 and the lid 60 with, for example, an adhesive or seam welding.

On an inner bottom surface 53 of the package 50, there are formed connection electrodes 56, 57. Further, on a second surface 54 of the package 50, there are formed external mounting terminals 58, 59. The connection electrode 56 is electrically coupled to the external mounting terminal 58 via a through electrode not shown provided to the package 50, and the connection electrode 57 is electrically coupled to the external mounting terminal 59 via a through electrode not shown provided to the package 50.

The resonator element 1 housed in the housing space 52 is fixed to the package 50 with a bonding member 61 as an electrically-conductive adhesive in a mount part of the thick-wall part 12 so that the principal surface at the positive side in the Y′ direction of the thick-wall part 12 faces to the package 50. The bonding member 61 is disposed so as to have contact with the connection electrode 56 and the pad electrode 33. Thus, the connection electrode 56 and the pad electrode 33 are electrically coupled to each other via the bonding member 61. By supporting the resonator element 1 at one place or a single point using the bonding member 61, it is possible to suppress, for example, the stress caused in the resonator element 1 by a difference in thermal expansion coefficient between the package 50 and the substrate 10.

The pad electrode 34 of the resonator element 1 is electrically coupled to the connection electrode 57 via a bonding wire 62. As described above, the pad electrode 34 is arranged so as to be opposed to the pad electrode 33, and is therefore located immediately above the bonding member 61 in the state in which the resonator element 1 is fixed to the package 50. Therefore, it is possible to suppress the leakage of the ultrasonic vibration provided to the pad electrode 34 when performing the wire bonding, and thus, it is possible to more reliably achieve the connection of the bonding wire 62 to the pad electrode 34.

By adopting such a configuration, since the resonator device 2 is provided with the resonator element 1 in which the thickness of the excitation electrodes 31, 32 is set to the thickness with which the unwanted spurious is difficult to occur, and the thickness of the extraction electrodes 35, 36 is set to the thickness with which the sheet resistance is difficult to increase, it is possible to obtain the resonator device 2 which has good vibration characteristics, and which is excellent in electrical reliability.

What is claimed is:

1. A method of manufacturing a resonator element including
a substrate having a thin-wall part and a thick-wall part larger in thickness than the thin-wall part, and
an electrode part having an excitation electrode arranged in an excitation electrode placement area of the thin-wall part, a pad electrode arranged in a pad electrode placement area of the thick-wall part, and an extraction electrode which is configured to couple the excitation electrode and the pad electrode to each other, and which is arranged in an extraction electrode placement area of the substrate, the method comprising:
a metal layer formation step of forming a metal layer on the substrate;
a protective film formation step of forming a protective film in an area overlapping at least a part of the extraction electrode placement area in a plan view on the metal layer; and
a metal layer etching step of etching the metal layer arranged in the excitation electrode placement area via the protective film to thereby reduce a wall thickness of the metal layer.

2. The method of manufacturing the resonator element according to claim 1, wherein
the metal layer formation step includes forming the metal layer having a thickness T1,
the metal layer etching step includes reducing the wall thickness of the metal layer arranged in the excitation electrode placement area to form the metal layer having a thickness T2, and
0.05≤T2/T1≤0.7 is fulfilled.

3. The method of manufacturing the resonator element according to claim 1, wherein
the extraction electrode placement area includes a first area including a portion located in the thick-wall part, and a second area including a portion located in the thin-wall part,
the protective film formation step includes forming the protective film in an area overlapping the first area in a plan view on the metal layer, and
the metal layer etching step includes etching the metal layer arranged in the second area and the excitation electrode placement area via the protective film to thereby reduce the wall thickness of the metal layer.

4. The method of manufacturing the resonator element according to claim 3, wherein
the protective film formation step includes forming the protective film in the pad electrode placement area, and an area overlapping the first area located in the thin-wall part in a plan view on the metal layer.

5. The method of manufacturing the resonator element according to claim 3, wherein
the substrate includes a connection part which is configured to connect the thick-wall part and the thin-wall part to each other, and which has a tilted part, and
the protective film formation step includes forming the protective film in the pad electrode placement area, and an area overlapping the first area located in the thin-wall part and the connection part in a plan view on the metal layer.

6. The method of manufacturing the resonator element according to claim 3, wherein
the metal layer etching step includes performing dry etching on the metal layer arranged in the second area and the excitation electrode placement area via the protective film to thereby reduce the wall thickness of the metal layer.

7. A resonator element comprising:
a substrate having a thin-wall part and a thick-wall part larger in thickness than the thin-wall part; and
an electrode part having an excitation electrode arranged in an excitation electrode placement area of the thin-wall part, a pad electrode arranged in a pad electrode placement area of the thick-wall part, and an extraction electrode which is configured to couple the excitation electrode and the pad electrode to each other, and which is arranged in an extraction electrode placement area of the substrate, wherein
the electrode part includes
a first electrode layer arranged in the pad electrode placement area, the extraction electrode placement area, and the excitation electrode placement area on the substrate, and
a second electrode layer which is arranged in an area overlapping the pad electrode placement area, the extraction electrode placement area, and the excitation electrode placement area in a plan view on the first electrode layer, and which is larger in thickness than the first electrode layer, and
the second electrode layer includes an electrode thin-wall part overlapping the excitation electrode placement area in a plan view, and an electrode thick-wall part which overlaps the extraction electrode placement area, and which is larger in thickness than the electrode thin-wall part.

8. The resonator element according to claim 7, wherein
defining a thickness of the electrode thick-wall part as T1, and
defining a thickness of the electrode thin-wall part as T2,
0.05≤T2/T1≤0.7 is fulfilled.

9. The resonator element according to claim 7, wherein
the extraction electrode placement area includes a first area including a portion located in the thick-wall part, and a second area including a portion located in the thin-wall part,
the electrode thin-wall part overlaps the second area and the excitation electrode placement area in a plan view, and
the electrode thick-wall part overlaps the first area and the pad electrode placement area in a plan view.

10. The resonator element according to claim 7, wherein
the second electrode layer is made of gold, and
the first electrode layer includes at least one of nickel, chromium, and chromium nitride.

11. The resonator element according to claim 7, wherein
a surface of the electrode thin-wall part at an opposite side to the substrate is an etched surface.

12. The resonator element according to claim 7, wherein
a surface of the electrode thin-wall part at an opposite side to the substrate is a dry-etched surface.

13. A resonator device comprising:
the resonator element according to claim 7; and
a package in which the resonator element is housed, and to which the resonator element is fixed via a bonding member.
